(19) United States
(12) Patent Application Publication
(10) Pub. No.: US 2013/0162964 A1
(43) Pub. Date: Jun. 27, 2013

(54) Lithographic Apparatus and Device Manufacturing Method

(71) Applicant: ASML NETHERLANDS B.V., Veldhoven (NL)

(72) Inventors: Ivo Adam Johannes THOMAS, Son (NL); Siebe LANDHEER, Eindhoven (NL)

(73) Assignee: ASML NETHERLANDS B.V., Veldhoven (NL)

(21) Appl. No.: 13/686,844

(22) Filed: Nov. 27, 2012

Related U.S. Application Data
(60) Provisional application No. 61/579,355, filed on Dec. 22, 2011.

(51) Int. Cl. G03F 7/20

(52) U.S. Cl. CPC G03F 7/70641
USPC 355/55

(57) ABSTRACT

Systems and methods provide the use of a two or three plate Alvarez lens located in a field plane of a projection lens of a lithographic apparatus. The Alvarez lens can be used to modify the shape of the focal plane to match a previously determined surface topography, while at the same time the Alvarez lens can be designed to include a built-in correction for astigmatism and other residual Zernike errors that would otherwise be introduced.

### FIELD

The present invention relates to a lithographic apparatus and a method for manufacturing a device.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Conventional lithographic apparatus include so-called steppers, in which each target portion is irradiated by exposing an entire pattern onto the target portion at once, and so-called scanners, in which each target portion is irradiated by scanning the pattern through the beam of radiation in a given direction (the “scanning” direction) while synchronously scanning the substrate parallel or anti-parallel to this direction.

### SUMMARY

According to an embodiment of the present invention there is provided a lithographic apparatus comprising a substrate table constructed to hold a substrate, a projection system configured to project a patterned radiation beam onto a target portion of the substrate, the projection system having a focal plane and comprising a manipulator capable of adjusting the shape of the focal plane only, and a controller, operative during an exposure for imaging the target portion, to control the manipulator to change the shape of the focal plane to more closely conform to the surface contour of the target portion.

In one example, the adjustable element is located in a field plane of the projection system although beneficial results may still be obtained if the adjustable element is located close to the field plane.

In one example, the manipulator includes a correction device adapted to provide a correction against astigmatism errors introduced by changing the shape of the focal plane,

In desired embodiments the manipulator comprises an Alvarez lens comprising at least two elements wherein the lens is adjusted by moving one element in a direction perpendicular to the optical axis of the lens. The lens may comprise two such elements with each element comprising a planar surface and a curved surface, with the curved surfaces of the two elements being complementary in shape. Alternatively the lens may comprises three elements, an outer pair of elements and a middle element located between the outer pair, each element of the outer pair comprising a planar surface and a curved surface facing the middle element, and the middle element comprising two curved surfaces, each curved surface of the middle element being complementary in shape to the facing curved surface.

In some embodiments of the present invention in addition to astigmatism the correction means corrects for other residual Zernike errors.

According to another aspect of the present invention there is provided a method of manufacturing a device using a lithographic apparatus comprising, projecting a patterned radiation beam onto a target portion of a substrate, deriving a map of the surface contour of the substrate at least in the region of the target, using a manipulator configured to change only the shape of the radiation beam in a focal plane to more closely confirm to the surface contour of the substrate in the target portion.

In one example, the manipulator is located in a field plane of the projection system although beneficial results may still be obtained if the manipulator located close to the field plane.

In another embodiment of the present invention the manipulator comprises an Alvarez lens comprising at least two elements wherein the lens is adjusted by moving one element in a direction perpendicular to the optical axis of the lens. The lens may comprise two such elements and with each element comprising a planar surface and a curved surface, with the curved surfaces of the two elements being complementary in shape. Alternatively the lens may comprise three elements, an outer pair of elements and a middle element located between the outer pair, each element of the outer pair comprising a planar surface and a curved surface facing the middle element, and the middle element comprising two curved surfaces, each curved surface of the middle element being complementary in shape to the facing curved surface.

In some embodiments of the present invention in addition to astigmatism the method further includes correcting for other residual Zernike errors.

The present invention also extends to a device manufactured by a lithographic apparatus according to the method.

Further features and advantages of the present invention, as well as the structure and operation of various embodiments of the present invention, are described in detail below with reference to the accompanying drawings. It is noted that the present invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the present invention and to enable a person skilled in the relevant art(s) to make and use the present invention.

FIG. 1 depicts a lithographic projection apparatus according to a first embodiment of the present invention.

FIG. 2 is a view showing how the wafer height is determined from measurements by the level sensor and the Z-interferometer.

FIGS. 3 to 6 are views showing various steps of the focus control and leveling procedure according to the present invention.

FIG. 7 is a plan view of a substrate table showing the sensors and fiducials used in the focus control and leveling procedure according to the present invention.

FIG. 8 are schematic views illustrating a two-part Alvarez lens for use in an embodiment of the present invention.

FIG. 9 schematically illustrates a three-part Alvarez lens for use in an embodiment of the present invention.

FIG. 10 illustrates a control system for use in embodiments of the present invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

This specification discloses one or more embodiments that incorporate the features of this invention. The disclosed embodiment(s) merely exemplify the present invention. The scope of the present invention is not limited to the disclosed embodiment(s). The present invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the present invention may be implemented in hardware, firmware, software, or any combination thereof. Embodiments of the present invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present invention may be implemented.

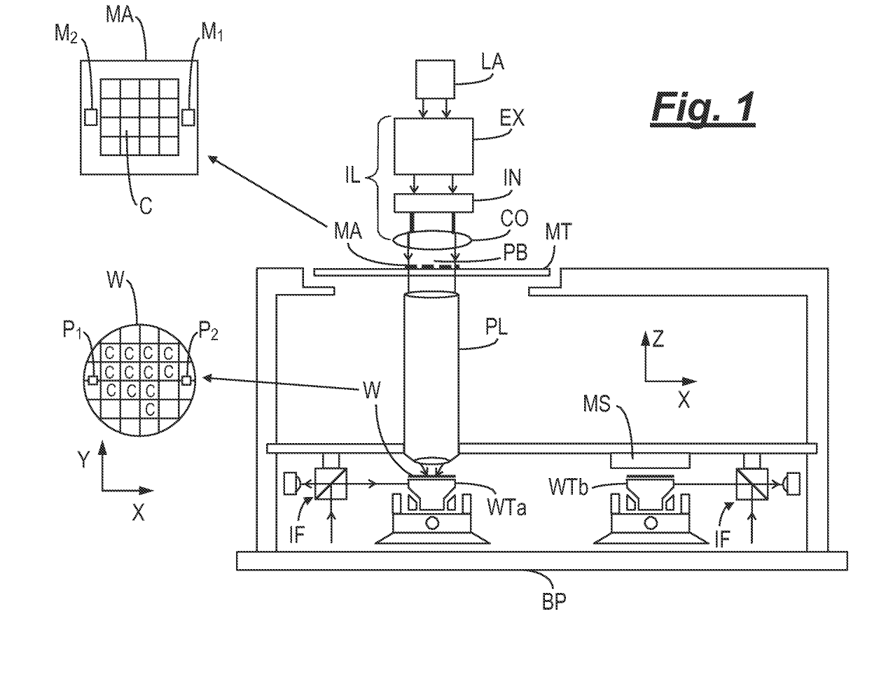

FIG. 1 schematically depicts a lithographic projection apparatus according to the present invention. The apparatus comprises: a radiation system LA, IL (Ex, IN, CO) for supplying a projection beam PB of radiation (e.g., UV or EUV radiation); a first object table (mask table) MT for holding a mask MA (e.g., a reticle), and connected to first positioning means for accurately positioning the mask with respect to item PL; a second object table (substrate or wafer table) WTa for holding a substrate W (e.g., a resist-coated silicon wafer), and connected to second positioning means for accurately positioning the substrate with respect to item PL; a third object table (substrate or wafer table) WTb for holding a substrate W (e.g., a resist-coated silicon wafer), and connected to third positioning means for accurately positioning the substrate with respect to item PL; a measurement system MS for performing measurement (characterization) processes on a substrate held on a substrate table WTa or WTb at a measurement station; and a projection system (“lens”) PL (e.g., a refractive or catadioptric system, a mirror group or an array of field deflectors) for imaging an irradiated portion of the mask MA onto an exposure area C (comprising one or more dies) of a substrate W held in a substrate table WTa or WTb at an exposure station.

As here depicted, the apparatus is of a transmissive type (i.e., has a transmissive mask). However, in general, it may also be of a reflective type, for example.

The radiation system may comprise a source LA (e.g., a Hg lamp, excimer laser, a laser-produced plasma source, a discharge plasma source, an undulator provided around the path of an electron beam in a storage ring or synchrotron, or an electron or ion beam source) which produces a beam of radiation. This beam is caused to traverse various optical components comprised in the illumination system IL (e.g., beam shaping optics Ex, an integrator IN and a condenser CO) so that the resultant beam PB has a desired shape and intensity distribution in its cross-section.

The beam PB subsequently intercepts the mask MA which is held on a mask table MT. Having traversed the mask MA, the beam PB traverses the projection system PL, which focuses the beam PB onto an exposure area C of the substrate W. With the aid of the interferometric displacement and measuring means IF, the substrate tables WTa, WTb can be moved accurately by the second and third positioning means, e.g., so as to position different exposure areas C in the path of the beam PB. Similarly, the first positioning means can be used to accurately position the mask MA with respect to the path of the beam PB using alignment marks M1,M2 and P1,P2. In general, movement of the object tables MT, WTa, WTb will be realized with the aid of a long stroke module (course positioning) and a short stroke module (fine positioning), which are not explicitly depicted in FIG. 1. In the case of a wafer stepper (as opposed to a step-and-scan apparatus) the mask table may be connected only to a short stroke positioning device, to make fine adjustments in mask orientation and position, or it may just be fixed.

The second and third positioning means may be constructed so as to be able to position their respective substrate tables WTa, WTb over a range encompassing both the exposure station under projection system PL and the measurement station under the measurement system MS. Alternatively, the second and third positioning means may be replaced by separate exposure station and measurement station positioning systems for positioning a substrate table in the respective exposure stations and a table exchange means for exchanging the substrate tables between the two positioning systems.

In general, lithographic apparatus contain a single mask table and a single substrate table. However, machines are known in which there are at least two independently movable substrate tables; see, for example, the multi-stage apparatus described in WO98/28665A and WO98/40791A, which are incorporated by reference herein in their entireties. The basic operating principle behind such multi-stage apparatus is that, while a first substrate table is at the exposure position underneath the projection system for exposure of a first substrate located on that table, a second substrate table can run to a loading position, discharge a previously exposed substrate, pick up a new substrate, perform some initial measurements on the new substrate and then stand ready to transfer the new substrate to the exposure position underneath the projection system as soon as exposure of the first substrate is completed; the cycle then repeats. In this manner it is possible to increase substantially the machine throughput, which in turn improves the cost of ownership of the machine. It should be understood that the same principle could be used with just one substrate table which is moved between exposure and measurement positions.

To correctly image the mask pattern onto the substrate it is necessary to position the wafer accurately in the focal plane of the projection lens. The position of the focal plane can vary according to the position of the mask, illumination and imaging settings in the illumination and projection systems and due to, for example, temperature and/or pressure variations in the apparatus, during an exposure or series of exposures. To deal with these variations in focal plane position, it is known to measure the vertical position of the focal plane using a sensor such as a transmission image sensor (TIS) or a reflection image sensor (RIS) and then position the wafer surface in the focal plane. This can be done using so-called “on-the-fly” leveling whereby a level sensor measures the vertical position of the wafer surface during the exposure and adjusts the height and/or tilt of the wafer table to optimize the imaging performance. Alternatively, so-called “off-axis” leveling can be used. In this method, a height map of (a part of) the wafer surface is taken, e.g., in a multi-stage apparatus, in advance of the exposure and height and tilt set points for the exposure, or series of exposures, to optimize the focus according to defined criteria, are calculated in advance. Methods and a system for such off-axis leveling are described in European Patent Application EP-A-1 037 117, which is incorporated by reference herein in its entirety. In the off-axis method, it is proposed that the exact shape and position of the focal plane be measured and the wafer height and tilt positions for the exposure can then be optimized to minimize defocus predicted relative to that measured focal plane. This provides improved results as compared to assuming that the focal plane is flat; nevertheless, since the focal plane will generally not have the same contour as the wafer surface, there will always be some residual defocus which cannot be compensated for by leveling procedures.

Known from the another example is EP1231515A, incorporated herein by reference in its entirety, which discloses that the shape of the focal plane can be adjusted using manipulators in the projection lens system and contemplates changing field curvature corrections or even deliberately introducing field curvature. A possible problem with this approach is that typically there is a strong coupling between field curvature and astigmatism curvature and changing the field curvature can introduce other errors.

An alternative approach to the problem is taken in US2010/0167189A, incorporated by reference herein in its entirety, which contemplates providing focus control by bending a reticle about a scan axis based on a mapped topology of the substrate. This proposal, however, presents a number of potential difficulties in manufacturing.

Suitable positioning systems are described, inter alia, in WO 98/28665 and WO 98/40791 mentioned above. It should be noted that a lithography apparatus may have multiple exposure stations and/or multiple measurement stations and that the numbers of measurement and exposure stations may be different than each other and the total number of stations need not equal the number of substrate tables. Indeed, the principle of separate exposure and measurement stations may be employed even with a single substrate table.

The depicted apparatus can be used in two different modes:

1. In step-and-repeat (step) mode, the mask table MT is kept essentially stationary, and an entire mask image is projected in one go (i.e., a single “flash”) onto an exposure area C. The substrate table WT is then shifted in the X and/or Y directions so that a different exposure area C can be irradiated by the beam PB;

2. In step-and-scan (scan) mode, essentially the same scenario applies, except that a given exposure area C is not exposed in a single “flash”. Instead, the mask table MT is movable in a given reference direction (the so-called “scan direction”, e.g., the Y direction) with a speed v, so that the projection beam PB is caused to scan over a mask image; concurrently, the substrate table WTa or WTb is moved in the same or opposite direction at a speed V=Mv, in which M is the magnification of the lens PL (typically, M=¼ or ⅕). In this manner, a relatively large exposure area C can be exposed, without having to compromise on resolution.

An important factor influencing the imaging quality of a lithographic apparatus is the accuracy with which the mask image is focused on the substrate. Wafers are generally polished to a very high degree of flatness but nevertheless deviations of the wafer surface from perfect flatness (referred to as “unflatness”) of sufficient magnitude noticeably to affect focus accuracy can occur. Unflatness may be caused, for example, by variations in wafer thickness, distortion of the shape of the wafer or contaminants on the substrate table. The presence of structures due to previous process steps also significantly affects the wafer height (flatness). In the present invention, the cause of unflatness is largely irrelevant; only the height of the top surface of the wafer is considered. Unless the context otherwise requires, references below to “the wafer surface” refer to the top surface of the wafer onto which will be projected the mask image.

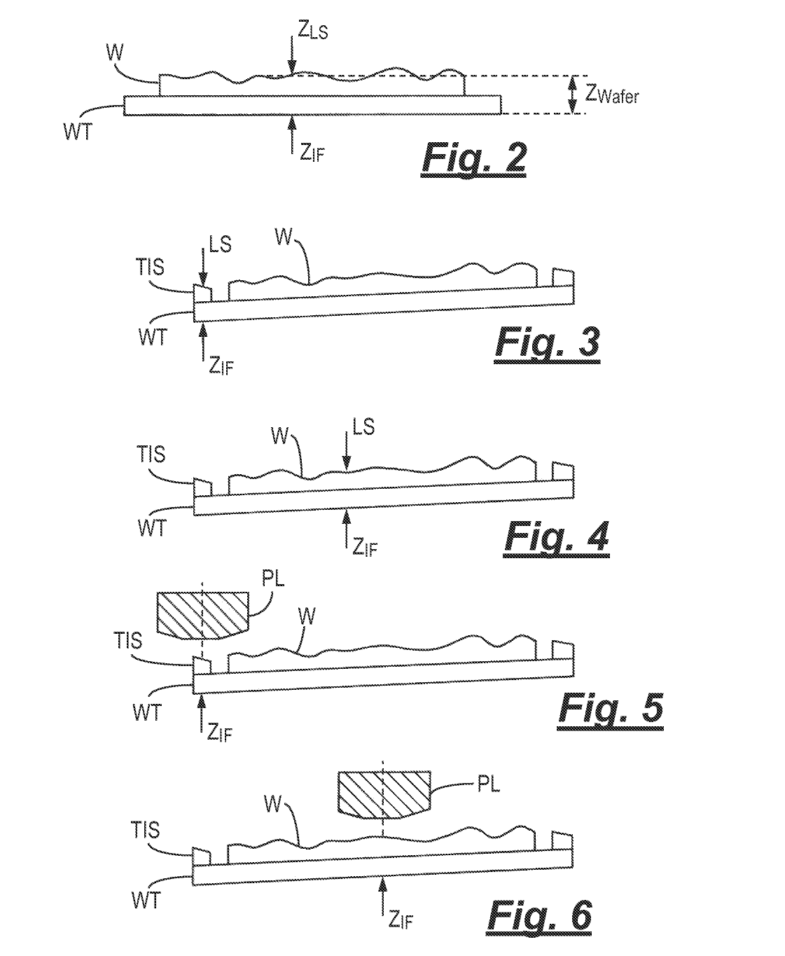

After loading a wafer onto one of the substrate tables WTa, WTb, the height of the wafer surface ZWafer relative to a physical reference surface of the substrate table is mapped. This process is carried out at the measurement station using a first sensor, referred to as the level sensor, which measures the vertical (Z) position of the physical reference surface and the vertical position of the wafer surface, ZLS, at a plurality of points, and a second sensor, for example a Z-interferometer, which simultaneously measures the vertical position of the substrate table, ZIF at the same points. As shown in FIG. 2, the wafer surface height is determined as ZWafer=ZLS-ZIF. The substrate table carrying the wafer is then transferred to the exposure station and the vertical position of the physical reference surface is again determined. The height map is then referred to in positioning the wafer at the correct vertical position during the exposure process. This procedure is described in more detail below with reference to FIGS. 3 to 7.

As shown in FIG. 3, first the substrate table is moved so that a physical reference surface fixed to the substrate table is underneath the level sensor LS. The physical reference surface may be any convenient surface whose position in X, Y and Z on the substrate table will not change during processing of a wafer in the lithographic apparatus and, most importantly, in the transfer of the substrate table between measurement and exposure stations. The physical reference surface may be part of a fiducial containing other alignment markers and the surface should have such properties as to allow its vertical position to be measured by the same sensor as measures the vertical position of the wafer surface. The physical reference surface may be a reflective surface in a fiducial in which is inset a so-called transmission image sensor (TIS). The TIS is described further below.

The level sensor may be, for example, an optical sensor; alternatively, pneumatic or capacitive sensors (for example) are conceivable. A presently desired form of sensor making use of Moire patterns formed between the image of a projection grating reflected by the wafer surface and a fixed detection grating is described in European Patent Application EP1037117A, incorporated by reference herein in its entirety. The level sensor should measure the vertical position of a plurality of positions on the wafer surface simultaneously and for each position the sensor may measure the average height of a particular area, so averaging out unflatnesses of high spatial frequencies.

Simultaneously with the measurement of the vertical position of a physical reference surface by the level sensor LS, the vertical position of the substrate table is measured using the Z-interferometer, ZIF. The Z-interferometer may, for example, be part of a three, five or six-axis interferometric metrology system such as that described in WO99/28790A or WO99/32940A, which documents are incorporated herein in their entirety by reference. The Z-interferometer system preferably measures the vertical position of the substrate table at a point having the same position in the XY plane as the calibrated measurement position of the level sensor LS. This may be done by measuring the vertical position of two opposite sides of the substrate table WT at points in line with the measurement position of the level sensor and interpolating/modeling between them. This ensures that, in the event that the substrate table is tilted out of the XY plane, the Z-interferometer measurement correctly indicates the vertical position of the substrate table under the level sensor.

Preferably, this process is repeated with at least a second physical reference surface spaced apart, e.g., diagonally, from the first physical reference surface. Height measurements from two or more positions can then be used to define a reference plane.

The simultaneous measurement of the vertical position of one or more physical reference surfaces and the vertical position of the substrate table establishes a point or points determining the reference plane relative to which the wafer height is to be mapped. A Z-interferometer of the type mentioned above is effectively a displacement sensor rather than an absolute sensor, and so requires zeroing, but provides a highly linear position measurement over a wide range. On the other hand, suitable level sensors, e.g., those mentioned above, may provide an absolute position measurement with respect to an externally defined reference plane (i.e., nominal zero) but over a smaller range. Where such sensors are used, it is convenient to move the substrate table vertically under the level sensor until the physical reference surface(s) is (are) positioned at a nominal zero in the middle of the measurement range of the level sensor and to read out the current interferometer Z value. One or more of these measurements on physical reference surfaces will establish the reference plane for the height mapping. The Z-interferometer is then zeroed with reference to the reference plane. In this way the reference plane is related to the physical surface on the substrate table and the ZWafer height map is made independent of the initial zero position of the Z-interferometer at the measurement station and other local factors such as any unflatness in the base plate over which the substrate table is moved. Additionally, the height map is made independent of any drift in the zero position of the level sensor.

As illustrated in FIG. 4, once the reference plane has been established, the substrate table is moved so that the wafer surface is scanned underneath the level sensor to make the height map. The vertical position of the wafer surface and the vertical position of the substrate table are measured at a plurality of points of known XY position and subtracted from each other to give the wafer height at the known XY positions. These wafer height values form the wafer height map which can be recorded in any suitable form. For example, the wafer height values and XY coordinates may be stored together in so-called indivisible pairs. Alternatively, the points at which wafer height values are taken may be predetermined, e.g., by scanning the wafer along a predetermined path at a predetermined speed and making measurements at predetermined intervals, so that a simple list or array of height values (optionally together with a small number of parameters defining the measurement pattern and/or a starting point) may suffice to define the height map.

The motion of the substrate table during the height mapping scan is largely only in the XY plane. However, if the level sensor LS is of a type which only gives a reliable zero reading, the substrate table is also moved vertically to keep the wafer surface at the zero position of the level sensor. The wafer height is then essentially derived from the Z movements of the substrate table, as measured by the Z-interferometer, necessary to maintain a zero readout from the level sensor. However, it is preferable to use a level sensor that has an appreciable measurement range over which its output is linearly related to wafer height, or can be linearized. Such measurement range ideally encompasses the maximum expected, or permissible, variation in wafer height. With such a sensor, the need for vertical movement of the substrate table during the scan is reduced or eliminated and the scan can be completed faster, since the scan speed is then limited by the sensor response time rather than by the ability of the short stroke positioning of the substrate table to track the contour of the wafer in three dimensions. Also, a sensor with an appreciable linear range can allow the heights at a plurality of positions (e.g., an array of spots) to be measured simultaneously.

Next, the wafer table is moved to the exposure station and, as shown in FIG. 5, the (physical) reference surface is positioned under the projection lens so as to allow a measurement of its vertical position relative to a reference point in the focal plane of the projection lens. In a desired embodiment, this is achieved using one or more transmission image sensors (described below) whose detector is physically connected to the reference surface used in the earlier measurements. The transmission image sensor(s) can determine the vertical focus position of the projected image from the mask under the projection lens. Armed with this measurement, the reference plane can be related to the focal plane of the projection lens and an exposure scheme which keeps the wafer surface in optimum focus can be determined. This is done by calculating a path for the substrate table in three-dimensions, e.g., defined by Z, Rx and Ry setpoints for a series of points along the scan path. This is shown in FIG. 6.

According to the present invention, the shape of the focal plane is also adjusted by means of field curvature correction in which the data concerning the surface topography is also used via the control means to adjust the field curvature in response to changes in the surface topography of the target as will be discussed below.

To provide the field curvature adjustment a manipulator comprising a two-element or a three-element variable-power aspherical lens of the type known as an Alvarez lens is provided at a field plane in the projection lens PL. Providing the manipulator at a field plane provides optimum results, but beneficial results may still be obtained if the manipulator is provided close to the field plane as may be necessary, for example, if the manipulator is provided in an existing manipulator slot by way of a “retro-fit” to an existing projection system.

The Alvarez lens is known from U.S. Pat. No. 3,305,294, incorporated herein by reference in its entirety, and an example of a two-element Alvarez lens pair is shown in FIG. 8. This lens pair consists of two identical bi-cubic phase profile optical lenses. Each part of the lens pair has a planar surface and a curved surface with the curved surfaces of the two parts of the lens pairs being complementary. The Alvarez lens is adjusted by introducing a relative lateral translational movement in a direction perpendicular to the optical axis as shown by the arrows in FIG. 8. The extent of the optical correction is proportional to the amount of relative movement. It should be noted that the extent of the curvature of the two curved surfaces is exaggerated in the figure for clarity. The two parts of the lens pair may be configured so that the curved surfaces face each other or so that the planar surfaces face each other.

FIG. 9 shows a three-element Alvarez lens in which a middle third part is introduced located between the first and second parts and which has two curved surfaces complementary to the curved surfaces of the first and second parts of the lens. Again the extent of the curvature is exaggerated for clarity. Again, adjustment of the lens is achieved by introducing relative lateral movement in a direction perpendicular to the optical axis. Either the two outer first and second parts may move relative to the middle third part, or the outer parts may be fixed and the middle part may move.

In embodiments of the present invention the manipulator comprising the Alvarez lens can be designed to provide a range of field curvature adjustments to match anticipated variations in the surface topography of the wafer. Doing this and nothing else would, however, create other non-correctible residual Zernike errors in the optical system that would have a negative effect on imaging, focus and overlay. By the term “Zernike errors” are intended any optical aberrations that may be described by Zernike polynomials. An important aspect of the present invention, at least in desired embodiments, is that the Alvarez lens is designed to introduce these errors itself with the opposite sign. This is possible because the optical system is linear. The result is that pure field curvature adjustment can be made without introducing other aberrations into the projection system.

In one embodiment of the present invention a two-element Alvarez lens is provided that is designed to provide a range of field curvature adjustments sufficient to match anticipated variations in the surface topology, while at the same time introducing changes in other optical parameters that will cancel out the otherwise non-correctible residual Zernike errors that will be introduced into the optical system by the adjustment to field curvature. If a two-element Alvarez lens does not provide a sufficient range to achieve these results then a three-element Alvarez lens can be used.

The Alvarez lens can be designed to produce the desired correction to the field curvature (the Z4 Zernike error), and at the same time can be configured to provide a pre-emptive correction for astigmatism and other residual Zernike errors, using techniques known from U.S. Pat. No. 3,305,294, incorporated by reference herein in its entirety.

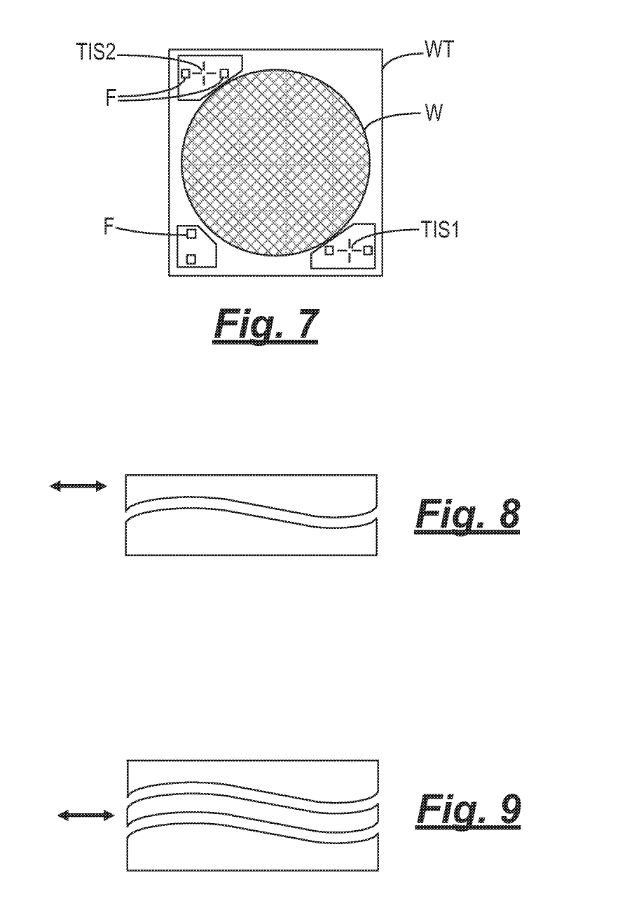

As mentioned above, the physical reference surface(s) is (are) preferably a surface in which a transmission image sensor (TIS) is inset. As shown in FIG. 7, two sensors TIS1 and TIS2 are mounted on a fiducial plate mounted to the top surface of the substrate table (WT, WTa or WTb), at diagonally opposite positions outside the area covered by the wafer W. The fiducial plate is made of a highly stable material with a very low coefficient of thermal expansion, e.g., Invar, and has a flat reflective upper surface which may carry fiducial markers F used in alignment processes. TIS1 and TIS2 are sensors used to determine directly the vertical (and horizontal) position of the aerial image of the projection lens. They comprise apertures in the respective surface close behind which is placed a photodetector sensitive to the radiation used for the exposure process. To determine the position of the focal plane, the projection lens projects into space an image of a TIS pattern TIS-M provided on the mask MA and having contrasting light and dark regions. The substrate table is then scanned horizontally (in one or preferably two directions) and vertically so that the aperture of the TIS passes through the space where the aerial image is expected to be. As the TIS aperture passes through the light and dark portions of the image of the TIS pattern, the output of the photodetector will fluctuate. This procedure is repeated at different vertical levels. The position at which the rate of change of amplitude of the photodetector output is highest indicates the position at which the image of TIS pattern has the greatest contrast and hence indicates the position of optimum focus. Thereby, a three-dimensional map of the focal plane can be derived. An example of a TIS of this type is described in greater detail in U.S. Pat. No. 4,540,277, incorporated herein by reference in its entirety. Instead of the TIS, a Reflection Image Sensor (RIS) such as that described in U.S. Pat. No. 5,144,363, incorporated herein by reference in its entirety, may also be used.

Using the surface of the TIS as the physical reference surface has the advantage that the TIS measurement directly relates the reference plane used for the height map to the focal plane of the projection lens, and so the height map can be employed directly to give height corrections for the substrate table during the exposure process. This is illustrated in FIG. 6, which shows the substrate table WT as positioned under the control of the Z-interferometer at a height determined by the height map so that the wafer surface is at the correct position under the projection lens PL.

The TIS surface may additionally carry reference markers whose position is detected using a through-the-lens (TTL) alignment system to align the substrate table to the mask. Such an alignment system is described in EP-0 467 445 A, incorporated herein by reference in its entirety, for example. Alignment of individual exposure areas can also be carried out, or may be obviated by an alignment procedure carried out at the measurement stage to align the exposure areas to the reference markers on the substrate table. Such a procedure is described in EP-0 906 590 A, incorporated herein by reference in its entirety, for example.

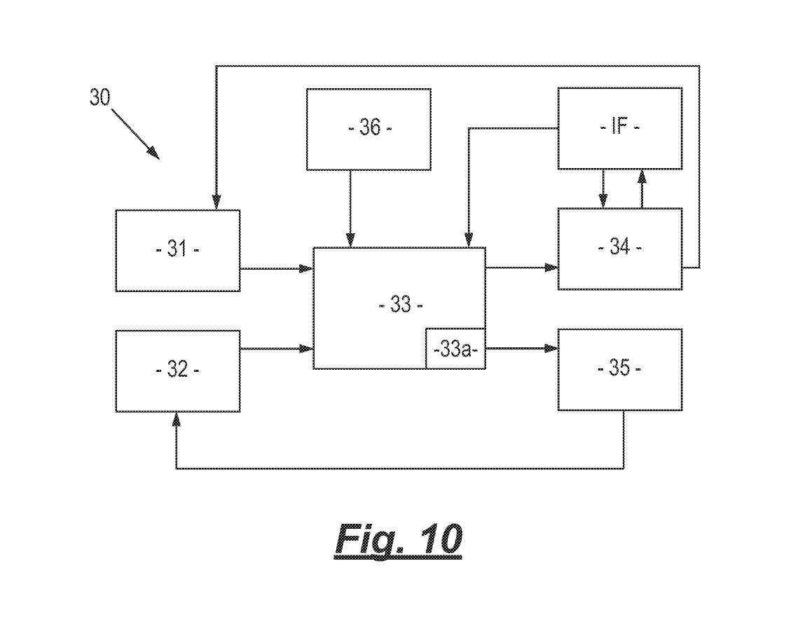

A control system 30 used in implementing the present invention is shown in FIG. 10. In FIG. 10, data describing the wafer surface is supplied by wafer height map 31, which may comprise a memory in which a previously derived wafer height map has been stored, or a level sensor directly measuring the wafer surface, in real time, and data describing the focal plane from focal plane map 32. Since it is generally impractical to continuously measure the configuration of the focal plane, the focal plane map 32 is generally a memory storing the results of periodic measurements of the focal plane shape, supplemented as necessary by a model of how the focal plane changes with varying imaging parameters. Where continuous or quasi-continuous measurement of the focal plane is possible, that may also be used. The data describing the wafer surface and the focal plane shape is used by controller 33 to calculate setpoints for the substrate table position (Z, Rx and Ry) and parameters for the Alvarez lens which are supplied to servo controller 34 for table positioning and servo controller 35 for control of the manipulator of the projection system PL. The table positioning servo controller 34 may employ a feedback control using the table position as measured by the interferometric displacement measuring system IF. The table position can also be used to control read-out from a memory 33a of setpoints calculated in advance. The adjustments to lens parameters, etc. can be fed back from the servo controller 35 to the focal plane map 32. The projection system may also be subject to adjustment to compensate for other, particularly transient, effects such as lens heating. Corrections to the projection system to effect the necessary compensations for such effects can be supplied by relevant control systems 36 and combined with adjustments for leveling and focusing according to the present invention.

The control system 30 also includes a feedback from servo controller 34 to wafer height map 31 to allow control of the substrate table position in real time (on-the-fly). This feedback can be omitted if only off-axis leveling - in which the substrate table positions during the scan are stored in advance in memory - is to be performed.

Where the wafer shape is primarily determined by previous process layers and a number of similar or identical dies are to be printed on one or more wafers, it may be possible to predict or calculate corrections only once for each die type in a wafer or batch of wafers. In some cases, the higher order wafer shape may be determined by previous process layers but superimposed on height and tilt variations across and between wafers and/or exposure areas. In such a case, the higher order corrections for each die type may be calculated in advance and combined with lower order corrections calculated for each exposure area.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled person will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The term “lens”, where the context allows, may refer to any one or combination of various types of optical components, including refractive, reflective, magnetic, electromagnetic and electrostatic optical components.

The term “EUV radiation” may be considered to encompass electromagnetic radiation having a wavelength within the range of 5-20 nm, for example within the range of 13-14 nm, or example within the range of 5-10 nm such as 6.7 nm or 6.8 nm.

While specific embodiments of the present invention have been described above, it will be appreciated that the present invention may be practiced otherwise than as described. For example, the present invention may take the form of a computer program containing one or more sequences of machine-readable instructions describing a method as disclosed above, or a data storage medium (e.g., semiconductor memory, magnetic or optical disk) having such a computer program stored therein. The descriptions above are intended to be illustrative, not limiting. Thus it will be apparent to one skilled in the art that modifications may be made to the present invention as described without departing from the scope of the claims set out below.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the present invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

What is claimed is:

1. A lithographic apparatus comprising:
a substrate table constructed to hold a substrate;
a projection system configured to project a patterned radiation beam onto a target portion of the substrate, the projection system having a focal plane and comprising a manipulator capable of adjusting a shape of a focal plane; and
a controller, operative during an exposure for imaging the target portion, configured to control the manipulator to change the shape of the focal plane to more closely conform to a surface contour of the target portion.

2. The apparatus of claim 1, wherein the manipulator is located in a field plane of the projection system.

3. The apparatus of claim 1, wherein the manipulator includes a correcting device adapted to provide a correction against astigmatism errors introduced by changing the shape of the focal plane.

4. The apparatus of claim 1, wherein:
the manipulator comprises an Alvarez lens comprising at least two elements; and
the lens is adjusted by moving one element in a direction perpendicular to an optical axis of the lens.

5. The apparatus of claim 4, wherein the lens comprises two the elements and each of the two elements comprises a planar surface and a curved surface, with the curved surfaces of the two elements being complementary in shape.

6. The apparatus of claim 4, wherein:
the lens comprises three the elements,
an outer pair of the elements and a middle element located between the outer pair,
each element of the outer pair comprising a planar surface and a curved surface facing the middle element,
the middle element comprising two curved surfaces, and
each curved surface of the middle element being complementary in shape to the facing curved surface.

7. The apparatus of claim 4, wherein in addition to astigmatism the correcting device corrects for other residual Zernike errors.

8. A method of manufacturing a device using a lithographic apparatus comprising,
projecting a patterned radiation beam onto a target portion of a substrate,
deriving a map of a surface contour of the substrate at least in a region of a target, and
using a manipulator configured to change a shape of a radiation beam in a focal plane to more closely conform to the surface contour of the substrate in the target portion.

9. The method of claim 8, further comprising locating the manipulator in a field plane of the projection system.

10. The method of claim 8, further comprising correcting for astigmatism errors introduced by changing the shape of the focal plane, wherein the shape of the radiation beam in the focal plane and the correction of the astigmatism errors is carried out by the manipulator.

11. The method of claim 8, wherein the manipulator comprises an Alvarez lens comprising at least two elements wherein the lens is adjusted by moving one element in a direction perpendicular to the optical axis of the lens.

12. The method of claim 11, wherein the lens comprises two the elements and each the element comprises a planar surface and a curved surface, with the curved surfaces of the two elements being complementary in shape.

13. The method of claim 11, wherein:
the lens comprises three the elements;
an outer pair of the elements and a middle element located between the outer pair,
each element of the outer pair comprising a planar surface and a curved surface facing the middle element,
the middle element comprising two curved surfaces, and
each curved surface of the middle element being complementary in shape to the facing curved surface.

14. The method of claim 11, further including correcting for other residual Zernike errors.
